(19) United States
(12) Patent Application Publication
(10) Pub. No.: US 2011/0101483 A1
(43) Pub. Date: May 5, 2011

(54) TWO COLOUR PHOTON DETECTOR

(75) Inventors: Christopher Laurence Jones, Southampton (GB); Leslie George Hipwood, Southampton (GB); Peter Knowles, Southampton (GB); Christopher David Maxey, Southampton (GB); Michael Allen Ordish, Southampton (GB)

(73) Assignee: Selex Sensors and Airborne Systems Limited, Southampton (GB)

(21) Appl. No.: 12/987,683

(22) Filed: Jan. 10, 2011

Related U.S. Application Data
(63) Continuation of application No. 10/545,573, filed on Aug. 16, 2005.

(30) Foreign Application Priority Data
Jun. 10, 2004 (EP) 04253481.8
Jun. 10, 2004 (GB) 0412942.5
Jun. 7, 2005 (GB) GB2005/050083

(51) Int. Cl. H01L 31/0232

(52) U.S. Cl. 257/432; 257/E31.127

(57) ABSTRACT

A two-colour radiation detector (2) comprises a mesa-type multi-layered mercury-cadmium-telluride detector structure monolithically integrated on a substrate (6). The detector (2) is responsive to two discrete wavelength ranges separated by a wavelength range to which the detector (2) is not responsive.

### RELATED APPLICATION

The application is a continuation of application Ser. No. 10/545,573 filed on Aug. 16, 2005, the entire content of which is hereby incorporated by reference in its entirety.

This invention relates to the field of solid state radiation detection, particularly to a two-colour radiation detector.

High performance, infrared photon detectors are commonly made from the narrow bandgap semiconductor mercury-cadmium-telluride (MCI) which generates electron-hole pairs when struck by infrared radiation. In this material the bandgap is dependent on the ratio of cadmium to mercury. For example, a detector made from Hg₁₋ₓCdₓTe with x=0.3 would respond, at a temperature of 80 K, to all wavelengths up to 5 μm. In practice a lower limit is set, either intentionally or unintentionally, by the presence of some other component in the optical path. For example, the lower limit could be set by using an optical filter that cut-on at 3 μm so the combination of filter and detector would then respond to all wavelengths between 3 μm and 5 μm. Such a conventional detector gives a signal proportional to the integrated photon flux in the wavelength band. However, the spectral distribution of emissions from a source can give information about the source and many applications require the ability to image a scene at infrared wavelengths in two different spectral bands, a capability commonly called “dual colour thermal imaging”. Such applications include rejection of background clutter, target discrimination and remote sensing for temperature determination and pollution monitoring.

Such dual-band MCI detector arrays comprise two separate photovoltaic detectors within each unit cell, one on top of the other. The photodiode with the shorter cut-off wavelength acts as a long-wavelength-pass filter for the longer cut-off photodiode. The use of two spatially coincident detectors that respond in different wavelength bands, the so-called two-colour detector, gives useful information about the source.

There are two principal types of MCT two-colour detectors—the metal-insulator-semiconductor (MIS) heterojunction detector and the triple layer heterojunction diode. The MIS heterojunction includes a thin wide bandgap N-type layer over a thick narrow bandgap n-type layer, where upper case letters denote a wide bandgap region or layer and lower case letters denote a narrow bandgap region or layer. The structure can detect radiation consistent with the wide bandgap layer or wide plus narrow bandgap layer, depending upon the voltage across the layers. However this structure requires precise control of both the layer thickness and the carrier concentration. It also only detects narrow and wide bandgap radiation separately.

The triple heterojunction diode includes back-to-back n-p-n diodes, one photodiode of long wavelength, LW, the other of mid wavelength, MW, for example. Operated by biasing between two terminals, one bias polarity results in the top (long wavelength, LW) photodiode of the bias-selectable detector being reverse-biased. The photocurrent of the MW photodiode is shunted by the low impedance of the forward-biased MW photodiode and the only photocurrent to emerge in the external circuit is the LW photocurrent, i.e. the bias-selectable detector has a long wavelength infrared (LWIR), 8-14 μm, detector response. When the bias voltage is reversed, the situation reverses. The LW photodiode is then forward-biased and the MW photodiode is reverse-biased. In this case the LW photocurrent is shunted and only the MW photocurrent is seen in the external circuit, i.e. the bias-selectable detector has a mid wavelength infrared (MWIR), 3-5 μm, detector response. This provides detection in two separate wavebands within each unit cell, with the optical areas of the two photodiodes spatially registered and co-located. Such co-location improves the accuracy of any calculation which assumes a single source for the two wavelengths of radiation. Even though the bias-selectable dual-band MCT detector affords spatial co-location of the two detectors, it does not allow temporal simultaneity of detection. Either one or other of the photodiodes is functioning, depending on the bias polarity applied across the back-to-back diode pair. Other problems also arise from the fact that it does not allow independent selection of the optimum bias for each photodiode and that there can be substantial MW cross-talk in the LW detector.

Some applications require simultaneity of detection in the two spectral bands. This has been achieved in an independently accessible two-colour IR detector, which provides independent electrical access to each of two spatially co-located back-to-back photodiodes. The P-n-N-P structure was formed by two Hg₁₋ₓCdₓTe layers grown sequentially onto a cadmium-zinc-telluride, CdZnTe, substrate.

Previously available two-colour detectors however are responsive in two overlapping wavelength bands. There is a need for two-colour detectors which respond in two non-adjacent wavelength bands, i.e. a detector in which two wavelength bands produce a signal, the two wavelength bands being separated by a wavelength band that does not produce a signal.

Accordingly, the present invention provides an electromagnetic radiation detector responsive to two discrete wavelength ranges. This allows the response of the detector to be matched to discrete atmospheric transmission windows that are separated by wavelength bands in which infrared radiation does not easily propagate. Complete separation or large spacing of the detection bands leads to an improved ability to characterise the temperature or wavelength of an external source, enabling machine intelligence to make a better asessment of the physical nature of the source. Applications of such a detector include clutter rejection and target identification.

Preferably, the detector comprises a plurality of layers of semiconductor material comprising: a substrate substantially transparent to electromagnetic radiation within and between the wavelength ranges; a first layer, doped to provide a first type of electrical conductivity, having a bandgap selected for absorbing radiation within a first wavelength range; a second layer, doped to provide a second type of electrical conductivity, having a bandgap selected for absorbing radiation within a second wavelength range, and a third layer, doped to provide the first type of electrical conductivity, having a bandgap selected for absorbing radiation within a third wavelength range.

The semiconductor material may be a Group II-VI semiconductor material.

Advantageously, the first and third layers are doped n-type and the second layer is doped p-type.

Ideally, a barrier is formed on either side of the second layer by providing a layer with an increased bandgap between the first and second layers and between the second and third layers.

Conveniently, an anti-reflection coating is disposed on a surface of the substrate, the substrate surface being a radiation-admitting surface of the detector.

The two wavelength ranges may be 2 μm to 2.5 μm and 3.7 μm to 4.5 μm.

The substrate may be comprised of gallium arsenide, GaAs; gallium arsenide on silicon, GaAs:Si; cadmium telluride, CdTe; cadmium zinc telluride, CdZnTe; cadmium telluride on silicon, CdTe:Si or cadmium telluride on sapphire, CdTe:sapphire.

In one embodiment, the lower limit of the first wavelength range is modified by alteration of the composition of a layer in the detector.

In an alternative embodiment, the lower limit of the first wavelength range is modified by an optical filter.

The invention will now be described by way of example and with reference to the accompanying drawings, in which:

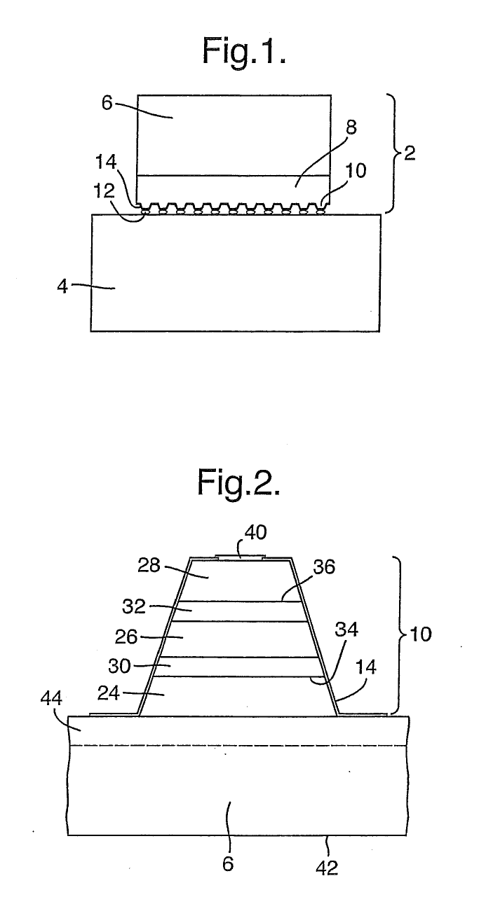

FIG. 1 shows a device in accordance with the invention bump-bonded to a silicon processor.

FIG. 2 is a cross-sectional view of a two-colour photon detector in accordance with the invention.

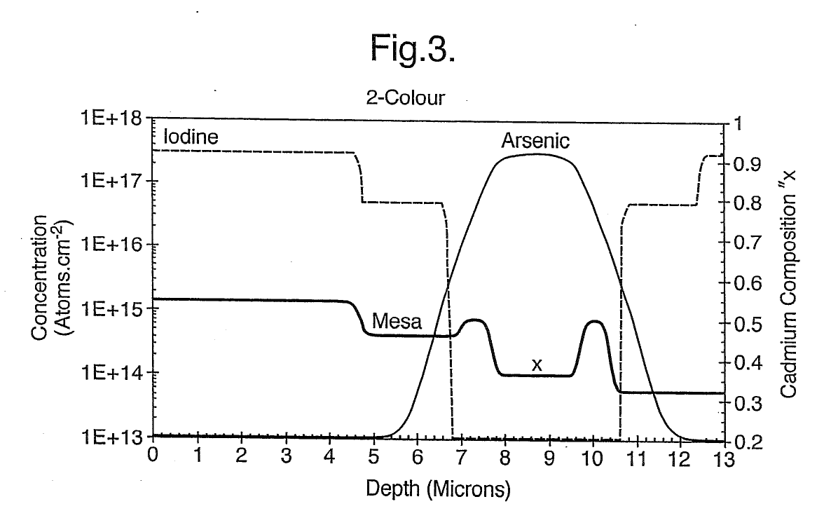

FIG. 3 shows the doping profiles and composition of a device such as that shown in FIG. 2.

FIG. 1 shows a two-colour photon detector 2 bump-bonded to a silicon processor 4. The detector 2 comprises a layer 8 of detector material attached to a substrate 6. Mesa structures 10 are formed in the detector material layer 8 to form a diode array and bumps 12 attach the detector 2 to the silicon processor 4 via each mesa 10. Exposed surfaces of the mesas 10 are covered with a passivation layer 14.

In FIG. 2, an enlarged view of part of FIG. 1, a two-colour photon detector includes a substrate 6 on which a mesa-type multi-layered MCT detector structure 10 is monolithically integrated. The detector may be grown by Liquid Phase Epitaxy (LPE), Molecular Beam Epitaxy (MBE), Vapour Phase Epitaxy (VPE) or by any process that is suitable for forming layers of Hg₁₋ₓCdₓTe, where the value of x is selected to set the bandgap energy of the Hg₁₋ₓCdₓTe to provide the desired spectral response for a given layer.

The MCT mesa structure 10 is comprised of a first layer 24 which is an n-type radiation absorbing layer, doped with, for example, iodine at a concentration of approximately 5×10¹⁶ atoms·cm⁻³. Overlying the first layer 24 is a p-type radiation absorbing layer 26 doped with, for example, approximately 3×10¹⁷ atoms·cm⁻³ of arsenic. Overlying absorbing layer 26 is a second layer of n-type radiation absorbing layer 28 doped with, for example, iodine at a concentration of approximately 5×10¹⁶ atoms·cm⁻³. The absorbing layers 26, 28 must be thick enough to absorb most of the incident photons. The required thickness can be roughly approximated as a thickness comparable to the wavelength of the photons being absorbed.

On either side of the second absorbing layer 26 is a barrier region of p-type HgCdTe material 30, 32. The barrier regions 30, 32 are designed to prevent the carriers generated by photons absorbed in the second absorbing layer 26 from escaping and appearing as a signal. The barrier regions 30, 32 must therefore be thick enough to prevent electrons tunnelling through. They are formed by increasing the bandgap at the interfaces between the absorbing layers 24, 26, 28. There are therefore two p-n junctions 34, 36 in the device, one at the interface between layers 24 and 30, the other at the interface between layers 32 and 28. They correspond to the points at which the arsenic and iodine dopant profiles cross (see FIG. 3).

Most absorption occurs in the region of the absorbing layer 24 on which the photons are incident. In the case of the first absorbing layer 24 (unlike the third absorbing layer 28), most absorption occurs in the region furthest from the junction 34. To ensure that the minority carriers (holes) photo-generated in the first absorbing layer 24 reach the p-n junction 34 before recombining, the diffusion length in the first absorbing layer 24 is designed to be greater than the thickness thereof. The diffusion length is controlled by the MCT composition and the doping. The MCT composition is fixed by the wavelengths to be detected so the doping level is chosen to give the required diffusion length.

On the other hand, the second absorbing layer 26 is heavily doped to minimise the minority carrier (electron) lifetime. To prevent the photons absorbed in the second absorbing layer 26 from producing a signal at the detector output, the photo-generated electrons in the second absorbing layer 26 are required to recombine as quickly as possible. The barrier regions 30, 32 on either side of absorbing layer 26 prevent the electrons that do not recombine from escaping.

Overlying exposed surfaces of the mesa structure 10 is an electrically insulating dielectric layer, preferably a wide bandgap passivation layer 14, such as a layer of cadmium telluride, CdTe, or zinc sulphide, ZnS. The passivation layer 14 beneficially reduces surface states by electronically combining with the states making them unavailable for surface conduction and improves the signal-to-noise ratio of the detector by reducing surface leakage currents. A suitable thickness for the passivation layer is between approximately 0.3 μm and 0.9 μm. Too thick a layer may stress the underlying MCT and thereby affect the diode performance. With too thin a layer, the required signal-to-noise ratio may not be attained.

The substrate 6 is comprised of, for example, gallium arsenide GaAs, epitaxial GaAs on silicon (GaAs:Si), CdZnTe, CdTe, CdTe:Si or CdTe:sapphire or other material that is substantially transparent to radiation having wavelengths of interest. In operation, radiation is incident upon a bottom surface 42 of the substrate 6. An anti-reflection coating may be applied to the bottom surface 42 of the substrate 6 to improve efficiency.

Within the substrate a common layer 44 of n-type electrical conductivity is formed. The interface between the common layer 44 and the first absorbing layer 24 is aligned with the base of the mesa. If the diffusion length in the first absorbing layer 24 is large compared with the distance between pixels (the array pitch), the etches between mesas (slots) need to penetrate the interface to prevent cross-talk, i.e. electron-hole pairs generated in the first absorbing layer 24 of one pixel leaking into the first absorbing layer of an adjacent pixel.

The common layer 44 is used to define the cut-on for wavelength band 1. With an MCT composition such that the layer absorbs all wavelengths below 2 μm for example, the common layer 44 is heavily doped to have a short diffusion length. Holes generated by wavelengths below 2 μm will not reach the junction 34 and so will not give a signal.

A bump 12 of indium or other suitable material is used to bond each mesa 10 to the silicon processor 4 via a window 40 etched in the passivation layer 14. Another metal may be deposited between the indium and the MCT to reduce the possibility of unwanted interdiffusion between the indium and the MCT.

A suitable bias potential is applied between the common layer 44 and the bump 12. For the connection to the common layer 44, the passivation on the diodes on the perimeter of the array is removed and a metal film deposited down the side of these mesas 10 to short the bump 12 to the common layer 44. The bumps 12 on these perimeter diodes are then used to connect to the common layer 44.

Photocurrents from the detector are read out using a multiplexer or Read Out Integrated Circuit (ROIC). An ROIC is a silicon integrated circuit designed for this purpose. For each diode in the array there is a corresponding input circuit in the ROIC. The indium bumps 12 are used to connect each diode to the corresponding input circuit. Each input circuit has a capacitor that stores photocurrent collected over a defined time period. The stored charges are then read out row by row and subsequently processed as required.

The metal organic vapour phase epitaxy (MOVPE) growth system used to grow the epitaxial layers of the mesa array cannot generate sharp arsenic concentration steps as arsenic diffuses significantly at the growth temperature. Spacer layers, not shown in FIG. 2, are used to ensure that, when allowance is made for diffusion of the arsenic, the junctions are formed in the required position. The doping and composition profiles shown in FIG. 3 illustrate how diffusion changes steps into grades for both arsenic and MCT composition but not for iodine, which has a very low diffusivity.

The mesas 10 are formed by defining a slot pattern in photoresist on the MCT layers using photolithography and etching away the exposed MCT to form slots. Such etches are isotropic (i.e. the etch goes sideways under the resist mask as well as down) and therefore the deeper the etch, the smaller the top of the mesa 10. As the top of each mesa is required to carry an indium bump, there is a limit to the thickness of the MCT layers. Typically, the mesa depth is approximately 8.5 μm with an array pitch of approximately 30 μm, although other depths and pitches are possible.

The photoresist is removed and the passivation layer 14 is deposited. Contact windows are defined in photoresist using photolithography, the passivation is etched away in the contact windows and the photoresist removed. Alternatively, a ‘lift-off’ process is used to define the contact windows. In the process, photolithography is used to place resist dots on the mesa tops, the passivation layer is deposited and the resist is then dissolved to lift-off the passivation on the resist dots. Similar processes are used to form the metal contacts to the mesa dots 40 and to the common layer and to form the indium bump interconnects. The wafer is then cut into die, each die being an array ready for bump-bonding to a multiplexer.

Having now described embodiments of the invention, numerous modifications will become apparent to the skilled person. For example, the cut-on for wavelength band 1 could be set by a suitable optical filter rather than or in addition to the composition of the common layer 44. The first absorbing layer 24 may be p-type MCT in which case the p-n junction is between the first absorbing layer 24 and the common layer 44. It is therefore preferable to etch the slot depth into the common layer 44 to prevent electrical cross-talk between adjacent pixels.

1. An electromagnetic radiation detector responsive to two non-adjacent wavelength ranges and comprising a plurality of layers of semiconductor material comprising:
a substrate substantially transparent to electromagnetic radiation within and between the wavelength ranges;
a first layer, doped to provide a first type of electrical conductivity, having a bandgap selected for absorbing radiation within a first wavelength range;
a second layer, doped to provide a second type of electrical conductivity, having a bandgap selected for absorbing radiation within a second wavelength range, and a third layer, doped to provide the first type of electrical conductivity, having a bandgap selected for absorbing radiation within a third wavelength range, wherein a barrier is formed on either side of the second layer by providing barrier layers with an increased bandgap such that a p-n junction is formed on either side of the second layer at an interface between each barrier layer and the first and third layers, respectively.

2. The detector as claimed in claim 1 wherein the semiconductor material is comprised of Group II-VI semiconductor material.

3. The detector as claimed in claim 1 wherein the first and third layers are doped n-type and the second layer is doped p-type.

4. The detector as claimed in claim 1 wherein one barrier layer of the barrier is located between the first and second layers and another barrier layer of the barrier is located between the second and third layers.

5. The detector as claimed in claim 1 further comprising an anti-reflection coating disposed on a surface of the substrate, the substrate surface being a radiation-admitting surface of the detector.

6. The detector as claimed in claim 1 wherein the two wavelength ranges are 2 μm to 2.5 μm and 3.7 μm to 4.5 μm.

7. The detector as claimed in claim 1 wherein the substrate is comprised of gallium arsenide, gallium arsenide on silicon, cadmium telluride, cadmium zinc telluride, cadmium telluride on silicon or cadmium telluride on sapphire.

8. The detector as claimed in claim 1 wherein a lower limit of the first wavelength range is modified by the composition of a layer in the detector.

9. The detector as claimed in claim 1 wherein a lower limit of the first wavelength range is modified by an optical filter.

10. The detector as claimed in claim 1 wherein the electromagnetic radiation detector is a photodiode.

11. The detector as claimed in claim 1, comprises:
a metal film deposited along sides of the first, second, and third layers.
